(19) United States
(12) Patent Application Publication
(10) Pub. No.: US 2010/0175620 A1
(43) Pub. Date: Jul. 15, 2010

(54) CHEMICAL VAPOR DEPOSITION APPARATUS

(75) Inventors: Motonobu TAKEYA, Seoul (KR); Sang Duk Yoo, Seongnam (KR); Sung Hwan Jang, Yongin (KR)

Correspondence Address: MCDERMOTT WILL & EMERY LLP, 18191 VON KARMAN AVE., SUITE 500, IRVINE, CA, 92612-7108, US

(73) Assignee: SAMSUNG LED CO., LTD., Suwon (KR)

(21) Appl. No.: 12/580,145

(22) Filed: Oct. 15, 2009

(30) Foreign Application Priority Data
Jan. 12, 2009 (KR) 10-2009-002398

(51) Int. Cl. C23C 16/00

(52) U.S. Cl. 118/715

(57) ABSTRACT

A chemical vapor deposition apparatus includes a substrate ceiling unit forming a reaction chamber to which a reaction gas is supplied to epitaxially grow a substrate, and an exhaust unit separated from the substrate ceiling unit and serving to discharge an exhaust gas after epitaxial growth reaction. The exhaust unit includes a particle formation part to which particles generated in the epitaxial growth of the substrate are attached.

### CROSS-REFERENCE TO RELATED APPLICATIONS

This application claims the priority of Korean Patent Application No. 10-2009-0002398 filed on Jan. 12, 2009, in the Korean Intellectual Property Office, the disclosure of which is incorporated herein by reference.

### BACKGROUND OF THE INVENTION

1. Field of the Invention

The present invention relates to a chemical vapor deposition apparatus, and more particularly, to a chemical vapor deposition apparatus, which can prevent particles from falling when the cover of a reaction chamber is opened for the replacement of a substrate.

2. Description of the Related Art

Various kinds of chemical vapor deposition (CVD) apparatuses are in use. In particular, a metal organic chemical vapor deposition (MOCVD) apparatus serves as a thin film forming apparatus that forms a metal oxide layer on a deposition object by chemical reaction. Using this apparatus, the vapor of an organic metallic compound with high vapor pressure is fed to a substrate heated inside a vacuum chamber, thereby growing a film of the metal on the substrate.

The MOCVD apparatus includes an exhaust unit disposed at the center of a reaction chamber. The exhaust unit is at a relatively low temperature even if an epitaxial (EPI) growth reaction takes place in the reaction chamber.

When a large amount of particles are generated due to the epitaxial growth reaction, the particles are attached to the wall or ceiling of the reaction chamber. However, particles around the exhaust unit with a relative low temperature have a low adhesive force, thus easily falling, even by slight vibrations, for example.

When the reaction chamber is opened for the replacement of a substrate, the particles may fall off the ceiling or walls, contaminating a substrate or a susceptor.

The contaminated substrate or susceptor may increase the time consumed in the process of cleaning, thereby lowering the operating rate of the equipment.

### SUMMARY OF THE INVENTION

An aspect of the present invention provides a chemical vapor deposition apparatus, which includes a separate exhaust unit unaffected by the opening or closing of a chamber cover, so that particles generated during an epitaxial growth reaction are prevented from falling due to the opening or closing operation of the chamber cover.

According to an aspect of the present invention, there is provided a chemical vapor deposition apparatus including: a substrate ceiling unit forming a reaction chamber to which a reaction gas is supplied to epitaxially grow a substrate; and an exhaust unit separated from the substrate ceiling unit and serving to discharge an exhaust gas after epitaxial growth reaction, the exhaust unit including a particle formation part to which particles generated in the epitaxial growth of the substrate are attached.

The substrate ceiling unit may be bent corresponding to a top portion of the particle formation part, to form an exhaust ceiling part.

The particle formation part may include a top plate and a bottom plate. The top plate may be connected with the bottom plate by a connection rod therebetween to form a space allowing the discharge of gas after reaction, and the bottom plate may have an exhaust hole.

The top plate may include a cover member placed on a bottom surface thereof to increase a cross-sectional area over which particles are attached.

The top plate may be bent to increase a cross-sectional area over which particles are attached.

The top plate may include a cone-shaped portion on a bottom surface thereof to increase a cross-sectional area over which particles are attached.

The particle formation part may include a top plate and a bottom plate. The top plate may be connected with the bottom plate by a connection rod therebetween to form a space allowing the discharge of gas after reaction, and the bottom plate may communicate with a body part having an exhaust path serving to discharge the exhaust gas.

The top plate may include a cover member placed on a bottom surface thereof to increase a cross-sectional area over which particles are attached.

The top plate may be bent to increase a cross-sectional area over which particles are attached.

The top plate may include a cone-shaped portion on a bottom surface thereof to increase a cross-sectional area over which particles are attached.

The exhaust unit may be supported, inserted in an exhaust mounting part, and be detachably mounted.

According to another aspect of the present invention, there is provided a chemical vapor deposition apparatus including: a reaction chamber cover covering a reaction chamber to which a reaction gas is supplied to epitaxially grow a substrate; a substrate ceiling unit connected to the reaction chamber cover, to which particles generated above the substrate are attached; and an exhaust unit separated from the substrate ceiling unit and serving to discharge an exhaust gas after an epitaxial growth reaction, the exhaust unit including a particle formation part to which particles generated in the epitaxial growth reaction are attached.

The reaction chamber cover may overlie a frame holding a susceptor, and be hinge-connected to a support frame provided outside the frame and supporting the reaction chamber cover, so as to cover the reaction chamber.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view of a chemical vapor deposition apparatus according to an exemplary embodiment of the present invention;

FIG. 2 is a schematic cross-sectional view depicting the state in which a cover of a reaction chamber is open after reaction in the reaction chamber of a chemical vapor deposition apparatus, according to an exemplary embodiment of the present invention;

FIG. 3 is a schematic perspective view of an exhaust unit according to an exemplary embodiment of the present invention;

FIG. 4 is a cross-sectional view taken along line A-A′ of FIG. 3;

FIG. 5 is a schematic cross-sectional view of an exhaust unit according to another exemplary embodiment of the present invention; and

FIGS. 6A through 6C are schematic perspective views depicting the top plates for an exhaust unit, according to exemplary embodiments of the present invention, respectively.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as limited to the embodiments set forth herein. Rather, these embodiments are provided so that this disclosure will be thorough and complete, and will fully convey the scope of the invention to those skilled in the art.

Like reference numerals in the drawings denote like elements.

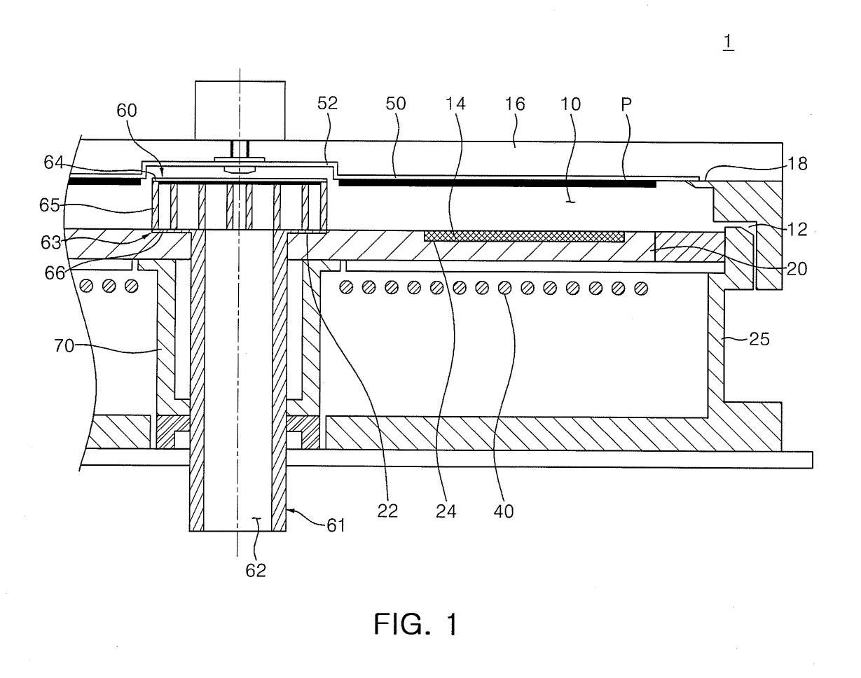

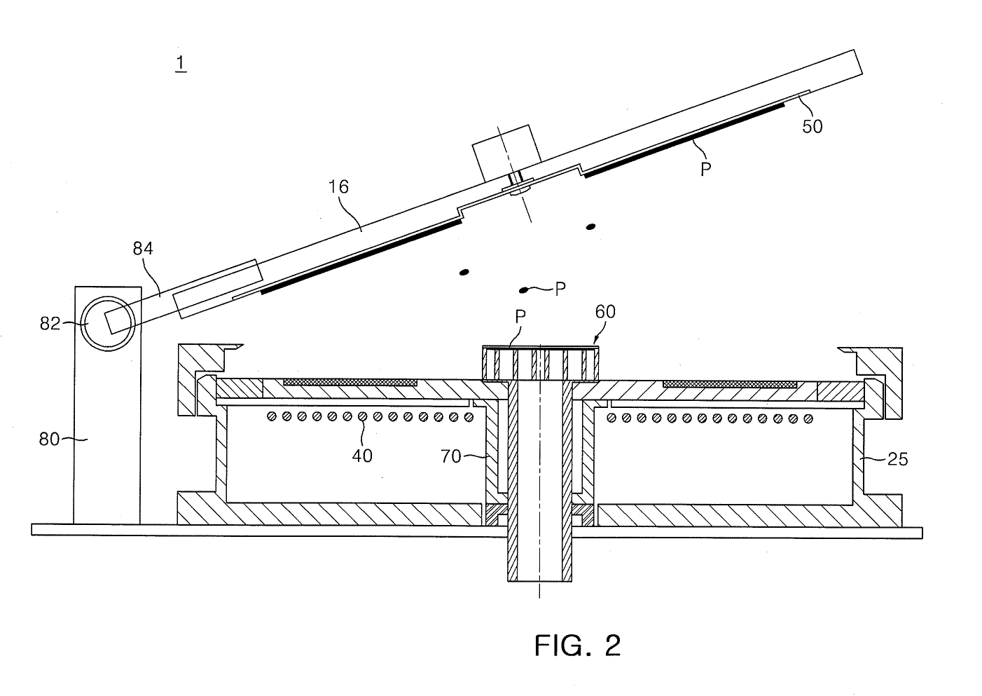

FIG. 1 is a schematic cross-sectional view of the portion of a chemical vapor deposition apparatus according to an exemplary embodiment of the present invention. FIG. 2 is a schematic cross-sectional view depicting the state in which the cover of a reaction chamber is open after reaction takes place in the reaction chamber of a chemical vapor deposition apparatus according to an exemplary embodiment of the present invention.

Referring to FIGS. 1 and 2, a chemical vapor deposition apparatus 1, according to an exemplary embodiment of the present invention, includes a substrate ceiling unit 50, and an exhaust unit 60.

According to another exemplary embodiment of the present invention, the chemical vapor deposition apparatus 1 may further include a reaction chamber cover 16 connected with the substrate ceiling unit 50.

The substrate ceiling unit 50 forms a reaction chamber 10 to which a reaction gas is supplied for the epitaxial growth of a substrate 14.

The reaction chamber 10 is a space in which a reaction gas flows to grow a thin film of the substrate 14 by chemical reaction. The reaction chamber 10 is formed by covering the space over the substrate 14 with the substrate ceiling unit 50.

The reaction chamber cover 16 overlies a frame 25 that holds a susceptor 20.

The reaction chamber cover 16 is connected to a reaction chamber cover support frame 80 (hereinafter, referred to as a support frame) by a cover connector 84. Here, the support frame 80 is disposed outside the frame 25 and supports the reaction chamber cover 16. The reaction chamber cover 16 covers the frame 25, swinging around a hinge 82 disposed at the support frame 80.

The substrate ceiling unit 50 is connected to the reaction chamber cover 16. As the reaction chamber cover 16 rotates, placing the substrate ceiling unit 50 on a substrate ceiling mounting part 18, the space over the substrate 14 is closed, thus forming the reaction chamber 10.

A heater 40 is provided under the susceptor 20 in order to supply heat to the substrate 14, received in the susceptor 20. The heater 40 is configured as an induction coil and supplies heat, generated due to electrical resistance, to the substrate 14 on the susceptor 20.

The heater 40 is absent around a rotation shaft 70. This leads to a relatively low temperature in the central portion of the reaction chamber 10 at which the exhaust unit 60 is disposed.

The reaction chamber 10 communicates with a gas inlet 12 serving to provide a reaction gas for the epitaxial growth of the substrate 14. The substrate 14 is received in the susceptor 20, exposed in the bottom of the reaction chamber 10.

The susceptor 20 has the shape of a round disk, and includes a substrate reception groove 24 receiving the substrate 14. The susceptor 20 may hold a plurality of substrates 14. The substrates 14 may correspond to each other with respect to the rotation shaft 70.

The rotation shaft 70 has a cylindrical shape. If the exhaust unit 60 is absent, the cylindrical interior of the rotation shaft 70 may serve as an exhaust path of an exhaust gas after reaction.

The exhaust unit 60 is disposed at the central portion of the reaction chamber 10. The exhaust unit 60 guides a reaction gas, injected into the reaction chamber 10 by the gas inlet 12, to the outside after reaction.

During the epitaxial growth reaction for the substrate 14, a large amount of particles are generated due to this gas-phase reaction. The generated particles are attached to the substrate ceiling unit 50 and the exhaust unit 60.

The exhaust unit 60 includes a particle formation part 63 to which particles generated due to the epitaxial growth of the substrate 14 are attached.

The substrate ceiling unit 50 extends over the entire reaction chamber 10. Here, the substrate ceiling unit 50 is bent corresponding to the top of the particle formation part 63 of the exhaust unit 60, thereby forming an exhaust ceiling part 52.

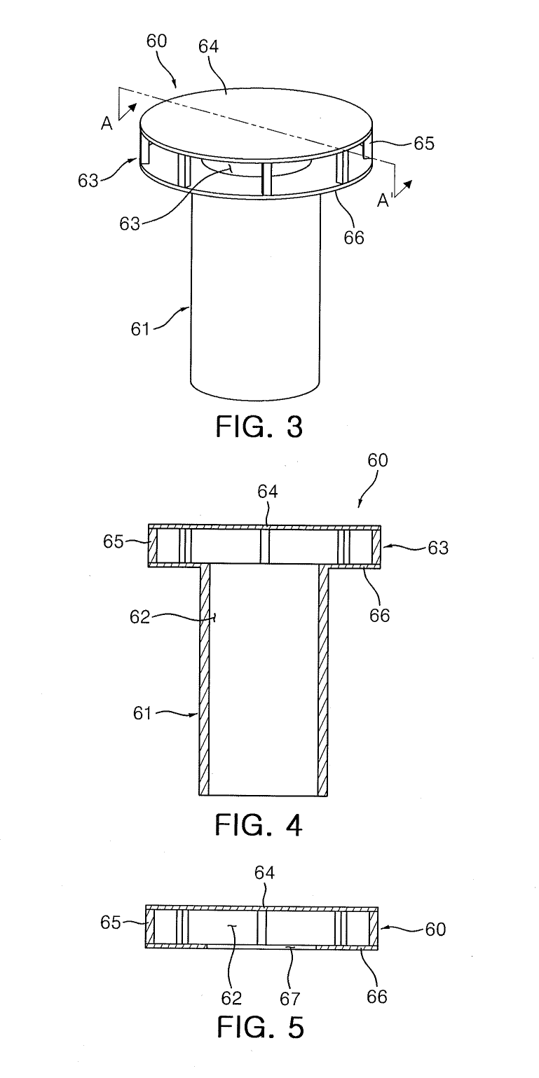

FIG. 3 is a schematic perspective view of an exhaust unit according to an exemplary embodiment of the present invention, and FIG. 4 is a cross-sectional view taken along line A-A′ depicted in FIG. 3.

The exhaust unit 60, according to this embodiment, includes the particle formation part 63 to which generated particles are attached, and a cylindrical body part 61 having an exhaust path 62 therein.

The particle formation part 63 includes a top plate 63 and a bottom plate 66. The top plate 64 is connected with the bottom plate 66 by at least one connection rod 65, thus forming a space therebetween. This space allows the discharge of gas after reaction.

The bottom plate 66 communicates with the body part 61 having the exhaust path 62 that serves to discharge exhaust gas.

In more detail, the exhaust unit 60 is supported, inserted in an exhaust mounting part 22 disposed at one side of the susceptor 20. Also, the exhaust unit 60 may be mounted detachably to the susceptor 20.

FIG. 5 is a schematic cross-sectional view of an exhaust unit according to another exemplary embodiment of the present invention.

Referring to FIG. 5, the exhaust unit 60, according to this embodiment, has only the particle formation part 63 to which generated particles are attached.

The particle formation part 63 includes the top plate 64 and the bottom plate 66. The top plate 64 is connected with the bottom plate 66 by a connection rod 65, thus forming a space therebetween. This space allows the discharge of gas after a reaction process.

The bottom plate 66 may have an exhaust hole 67 serving to discharge exhaust gas.

As in the previous embodiment, the exhaust unit 60 of this embodiment is supported, inserted in the exhaust mounting part 22 at one side of the susceptor 20. Also, the exhaust unit 60 may be mounted detachably to the susceptor 20.

According to the embodiments of the present invention, the temperature of the exhaust unit 60 is lower than that of the susceptor 20, which causes particles generated around the exhaust unit 60 to easily fall. However, the exhaust unit 60, according to the embodiments of the present invention, is supported to the exhaust mounting part 22 and is unaffected even by the opening the reaction chamber cover 16, so that particles are prevented from falling.

When the reaction chamber cover 16 is open, the exhaust unit 60 may be detached separately in order to remove the particles on the exhaust unit 60. Therefore, the particles of the exhaust unit 60 can be removed cleanly.

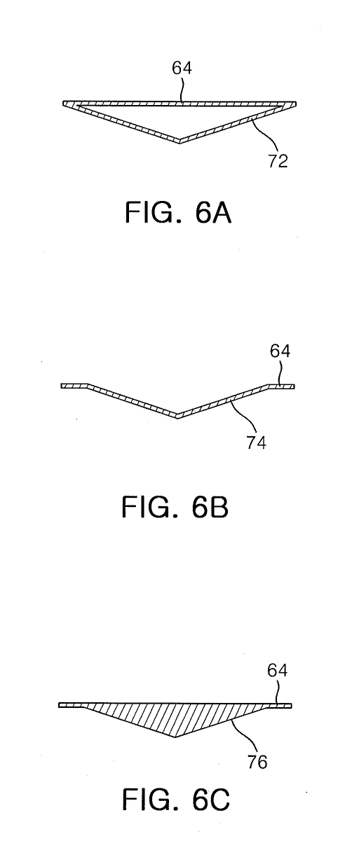

FIGS. 6A through 6C are schematic cross-sectional views of top plates for the exhaust unit, according to exemplary embodiments of the present invention, respectively.

FIGS. 6A through 6C illustrate various embodiments of the top plate 64. These various embodiments are designed to increase the cross-sectional area over which particles are attached in the bottom surface of the top plate 64.

FIG. 6A depicts a separate cover member 72 provided on the bottom surface of the top plate 64. FIG. 6B depicts the top plate 64 having a bent portion 74 having the shape of a cone. FIG. 6C depicts a cone-shaped portion 76 of the top plate 64, which is formed by varying the thickness of the top plate 64 from the center toward the outer edge thereof.

The aforementioned shapes serve to increase the amount of particles being attached to the top plate 64.

In the chemical vapor deposition apparatus according to the exemplary embodiments of the present invention, the exhaust unit where the temperature is relatively low is unaffected by the opening or closing of the chamber cover, unlike a substrate ceiling unit that opens or shuts with the opening or closing of the chamber cover. Therefore, vibration does not occur in the opening and closing of the chamber cover. Accordingly, particles generated around the exhaust unit are prevented from falling down onto the substrate or susceptor.

Also, the exhaust ceiling part may be separated for the process of cleaning. This reduces the time consumed for cleaning, and improves the operating rate of equipment.

As set forth above, according to exemplary embodiments of the invention, the chemical vapor deposition apparatus includes the exhaust unit unaffected by the opening or closing of the chamber cover, as well as the substrate ceiling unit that becomes open or closed when the chamber cover swings open or closed. Thus, vibrations are not generated even by the opening and closing of the chamber cover, so that particles generated around the exhaust unit having a relatively low temperature do not fall down onto the substrate or susceptor.

The exhaust unit can be cleaned after being detached, thereby reducing the time required for the cleaning process and increasing the operating rate of the equipment.

While the present invention has been shown and described in connection with the exemplary embodiments, it will be apparent to those skilled in the art that modifications and variations can be made without departing from the spirit and scope of the invention as defined by the appended claims.

What is claimed is:

1. A chemical vapor deposition apparatus comprising:
a substrate ceiling unit forming a reaction chamber to which a reaction gas is supplied to epitaxially grow a substrate; and
an exhaust unit separated from the substrate ceiling unit and serving to discharge an exhaust gas after epitaxial growth reaction, the exhaust unit including a particle formation part to which particles generated in the epitaxial growth of the substrate are attached.

2. The chemical vapor deposition apparatus of claim 1, wherein the substrate ceiling unit is bent corresponding to a top portion of the particle formation part, to form an exhaust ceiling part.

3. The chemical vapor deposition apparatus of claim 1, wherein the particle formation part includes a top plate and a bottom plate,
wherein the top plate is connected with the bottom plate by a connection rod therebetween to form a space allowing the discharge of gas after reaction, and
the bottom plate has an exhaust hole.

4. The chemical vapor deposition apparatus of claim 3, wherein the top plate includes a cover member placed on a bottom surface thereof to increase a cross-sectional area over which particles are attached.

5. The chemical vapor deposition apparatus of claim 3, wherein the top plate is bent to increase a cross-sectional area over which particles are attached.

6. The chemical vapor deposition apparatus of claim 3, wherein the top plate includes a cone-shaped portion on a bottom surface thereof to increase a cross-sectional area over which particles are attached.

7. The chemical vapor deposition apparatus of claim 1, wherein the particle formation part includes a top plate and a bottom plate,
wherein the top plate is connected with the bottom plate by a connection rod therebetween to form a space allowing the discharge of gas after reaction, and
the bottom plate communicates with a body part having an exhaust path serving to discharge the exhaust gas.

8. The chemical vapor deposition apparatus of claim 7, wherein the top plate includes a cover member placed on a bottom surface thereof to increase a cross-sectional area over which particles are attached.

9. The chemical vapor deposition apparatus of claim 7, wherein the top plate is bent to increase a cross-sectional area over which particles are attached.

10. The chemical vapor deposition apparatus of claim 7, wherein the top plate includes a cone-shaped portion on a bottom surface thereof to increase a cross-sectional area over which particles are attached.

11. The chemical vapor deposition apparatus of claim 1, wherein the exhaust unit is supported, inserted in an exhaust mounting part, and is detachably mounted.

12. A chemical vapor deposition apparatus comprising:
a reaction chamber cover covering a reaction chamber to which a reaction gas is supplied to epitaxially grow a substrate;
a substrate ceiling unit connected to the reaction chamber cover, to which particles generated above the substrate are attached; and
an exhaust unit separated from the substrate ceiling unit and serving to discharge an exhaust gas after an epitaxial growth reaction, the exhaust unit including a particle formation part to which particles generated in the epitaxial growth reaction are attached.

13. The chemical vapor deposition apparatus of claim 12, wherein the reaction chamber cover overlies a frame holding a susceptor, and is hinge-connected to a support frame provided outside the frame and supporting the reaction chamber cover, so as to cover the reaction chamber.
